(19) United States
(12) Patent Application Publication
(10) Pub. No.: US 2025/0297064 A1
(43) Pub. Date: Sep. 25, 2025

(54) POLYMER FILM, LAMINATE, AND LAMINATE WITH METAL

(71) Applicant: FUJIFILM Corporation, Tokyo (JP)

(72) Inventors: Miyoko SHIBANO, Kanagawa (JP); Yasuyuki SASADA, Kanagawa (JP)

(73) Assignee: FUJIFILM Corporation, Tokyo (JP)

(21) Appl. No.: 19/228,716

(22) Filed: Jun. 4, 2025

Related U.S. Application Data
(63) Continuation of application No. PCT/JP2023/040817, filed on Nov. 13, 2023.

(30) Foreign Application Priority Data
Dec. 9, 2022 (JP) 2022-197495

(51) Int. Cl. C08G 69/44; C08J 5/18; C08K 3/38; C09K 19/38

(52) U.S. Cl. CPC C08G 69/44; C08J 5/18; C08K 3/38; C09K 19/3809; C08J 2377/12; C08K 2003/385; C08K 2201/014; C09K 2219/03

(57) ABSTRACT

A polymer film including a polymer, in which the polymer film has an elastic modulus of 10 MPa or less at 160° C., an elastic modulus of 0.1 MPa or more at 260° C., an equilibrium moisture absorptivity of 2.5% by mass or less at 85° C. and a relative humidity of 85%, and a dielectric loss tangent of 0.01 or less; a laminate including a layer B containing a polymer, in which the layer B has an elastic modulus of 10 MPa or less at 160° C. and an elastic modulus of 0.1 MPa or more at 260° C., and the laminate has an equilibrium moisture absorptivity of 2.5% by mass or less at 85° C. and a relative humidity of 85% and a dielectric loss tangent of 0.01 or less; and a metallized laminate including the polymer film or the laminate and a metal layer or a metal wire.

### CROSS-REFERENCE TO RELATED APPLICATION

This application is a Continuation of International Application No. PCT/JP2023/040817, filed Nov. 13, 2023, which claims priority to Japanese Patent Application No. 2022-197495, filed Dec. 9, 2022. Each of the above applications is hereby expressly incorporated by reference, in its entirety, into the present application.

### BACKGROUND OF THE INVENTION

### 1. Field of the Invention

The present disclosure relates to a polymer film, a laminate, and a metallized laminate.

### 2. Description of the Related Art

In recent years, frequencies used in a communication equipment tend to be extremely high. In order to suppress transmission loss in a high frequency band, insulating materials used in a circuit board are required to have a lowered relative permittivity and a lowered dielectric loss tangent. A copper-clad laminated plate is suitably used as a member constituting a circuit board, and a polymer film is suitably used for producing the copper-clad laminated plate.

For example, JP2022-126429A describes a polymer film including a layer A, and a layer B provided on at least one surface of the layer A, in which the layer A contains a polymer having a dielectric loss tangent of 0.01 or less, the layer B has a moisture permeability of less than 100 g/(m²·day) at a temperature of 40° C. and a relative humidity of 90%.

### SUMMARY OF THE INVENTION

Typically, a copper-clad laminated plate is produced by laminating a copper foil on a surface of a polymer film. In addition, the wiring board is produced by superimposing a copper-clad laminated plate and a wiring substrate such that a polymer film in the copper-clad laminated plate and the wiring substrate are in contact with each other. In a case of producing a wiring board, from the viewpoint of adhesiveness, it is required that the polymer film deforms by following the step formed on the surface of the wiring substrate.

On the other hand, in a case where a polymer film having excellent step followability with respect to the wiring substrate is used for the copper-clad laminated plate, interlayer peeling may occur in a reflow soldering step performed in a case of mounting an electronic component. Therefore, it has been required to achieve both excellent step followability with respect to the wiring substrate and excellent adhesiveness during reflow soldering (that is, excellent heat resistance).

An object to be achieved by an embodiment of the present disclosure is to provide a polymer film having excellent step followability and excellent heat resistance.

In addition, an object to be achieved by another embodiment of the present disclosure is to provide a laminate and a metallized laminate, which have excellent step followability and heat resistance.

The means for achieving the above-described objects include the following aspects.
<1> A polymer film including
a polymer,
in which the polymer film has
   an elastic modulus of 10 MPa or less at 160° C.,
   an elastic modulus of 0.1 MPa or more at 260° C.,
   an equilibrium moisture absorptivity of 2.5% by mass or less at 85° C. and a relative humidity of 85%, and
   a dielectric loss tangent of 0.01 or less.
<2> The polymer film according to <1>, in which the polymer contains a liquid crystal polymer.
<3> The polymer film according to <1> or <2>, in which the polymer contains an aromatic polyester amide.
<4> The polymer film according to any one of <1> to <3>, further including a thermoplastic resin containing a unit which is based on a monomer having an aromatic hydrocarbon group.
<5> The polymer film according to <4> including at least one of a curing agent or a cured product of the curing agent and the thermoplastic resin, in which the curing agent has at least one of an epoxy group or a maleimide group.
<6> The polymer film according to any one of <1> to <5>, further including at least one inorganic filler selected from the group consisting of silica, aluminum hydroxide, and boron nitride.
<7> A laminate including:
a layer A; and
a layer B provided on at least one surface of the layer A,
in which the layer B contains a polymer, has an elastic modulus of 10 MPa or less at 160° C., and has an elastic modulus of 0.1 MPa or more at 260° C., and
the laminate has an equilibrium moisture absorptivity of 2.5% by mass or less at 85° C. and a relative humidity of 85%, and a dielectric loss tangent of 0.01 or less.
<8> The laminate according to <7>, in which a ratio of an elastic modulus of the layer A at 160° C. to the elastic modulus of the layer B at 160° C. is 50 or more.
<9> The laminate according to <7> or <8>, in which the polymer contains a liquid crystal polymer.
<10> The laminate according to <7> or <8>, in which the polymer contains an aromatic polyester amide.
<11> The laminate according to any one of <7> to <10>, further including a thermoplastic resin containing a unit which is based on a monomer having an aromatic hydrocarbon group.
<12> The laminate according to <11> including at least one of a curing agent or a cured product of the curing agent and the thermoplastic resin, in which the curing agent has at least one of an epoxy group or a maleimide group.
<13> The laminate according to any one of <7> to <12>, further including at least one inorganic filler selected from the group consisting of silica, aluminum hydroxide, and boron nitride.
<14> The laminate according to any one of <7> to <13>, further including:
a layer C,
in which the layer B, the layer A, and the layer C are provided in this order.
<15> A metallized laminate including the polymer film according to any one of <1> to
<6> or the laminate according to any one of <7> to <14>, and a metal layer or a metal wire disposed on at least one surface of the polymer film or the laminate.
<16> The metallized laminate according to <15>, in which a peel strength between the polymer film or the laminate and the metal layer or the metal wire at 260° C. is 0.02 kN/m or more.

According to one embodiment of the present disclosure, it is possible to provide a polymer film having excellent step followability and excellent heat resistance.

In addition, according to another embodiment of the present disclosure, it is possible to provide a laminate and a metallized laminate which have excellent step followability and excellent heat resistance.

### DESCRIPTION OF THE PREFERRED EMBODIMENTS

Hereinafter, the contents of the present disclosure will be described in detail. The description of configuration requirements below is made based on representative embodiments of the present disclosure in some cases, but the present disclosure is not limited to such embodiments.

In the present specification, a numerical range shown using “to” indicates a range including numerical values described before and after “to” as a lower limit value and an upper limit value.

In a numerical range described in a stepwise manner in the present disclosure, an upper limit value or a lower limit value described in one numerical range may be replaced with an upper limit or a lower limit in another numerical range described in a stepwise manner. In addition, in a numerical range described in the present disclosure, an upper limit value or a lower limit value described in the numerical range may be replaced with a value described in an example.

In addition, in a case where substitution or unsubstitution is not noted in regard to the notation of a “group” (atomic group) in the present specification, the “group” includes not only a group that does not have a substituent but also a group having a substituent. For example, the concept of an “alkyl group” includes not only an alkyl group that does not have a substituent (unsubstituted alkyl group) but also an alkyl group having a substituent (substituted alkyl group).

Further, the term “step” in the present specification indicates not only an independent step but also a step which cannot be clearly distinguished from other steps as long as the intended purpose of the step is achieved.

Furthermore, in the present disclosure, a combination of two or more preferred embodiments is a more preferred embodiment.

In addition, the weight-average molecular weight (Mw) and the number-average molecular weight (Mn) in the present disclosure are molecular weights in terms of polystyrene used as a standard substance, which are detected by using a solvent tetrahydrofuran (THF), a differential refractometer, and a gel permeation chromatography (GPC) analyzer using TSKgel GMHxL, TSKgel G4000HxL, and TSKgel G2000HxL (all trade names manufactured by Tosoh Corporation) as columns, unless otherwise specified.

In the present disclosure, the “polymer” is a compound having a weight-average molecular weight of 3000 or more and a glass transition temperature higher than 25° C.

In the present disclosure, the “elastomer” is a compound having a weight-average molecular weight of 3,000 or more and a glass transition temperature of 25° C. or lower.

In the present disclosure, the glass transition temperature is measured by differential scanning calorimetry (DSC). For example, the measurement can be performed using a product name “DSC-60A Plus” (manufactured by Shimadzu Corporation) or the like. A temperature rising rate in the measurement is set to 10° C./minute.

### Polymer Film

The polymer film according to the present disclosure includes a polymer, in which the polymer film has an elastic modulus of 10 MPa or less at 160° C., an elastic modulus of 0.1 MPa or more at 260° C., an equilibrium moisture absorptivity of 2.5% by mass or less at 85° C. and a relative humidity of 85%, and a dielectric loss tangent of 0.01 or less.

As a result of intensive studies, the inventors of the present invention have found that a polymer film having excellent step followability and excellent heat resistance can be provided by adopting the above-described configuration.

The detailed mechanism that brings about the aforementioned effect is unclear, but is assumed to be as below.

In the polymer film according to the present disclosure, it is presumed that the elastic modulus of the layer B at 160° C. is 10 MPa or less, and thus, the layer B is deformed according to the stepped shape during lamination by a heat press, which improves the step followability.

In addition, in the polymer film according to the present disclosure, the equilibrium moisture absorptivity at 85° C. and a relative humidity of 85% is 2.5% by mass or less, and thus the polymer film is less likely to absorb moisture and is less likely to cause interlayer peeling due to heating. That is, the heat resistance is excellent.

From the viewpoint of step followability, the elastic modulus of the polymer film at 160° C. is preferably 0.1 MPa to 8 MPa, more preferably 0.3 MPa to 5 MPa, and still more preferably 0.5 MPa to 4 MPa.

In the present disclosure, the elastic modulus of the polymer film at 160° C. is measured by the following method.

First, a film cross-section sample (length: 2 mm×width: 2 mm) produced by oblique cutting with a microtome to a thickness of 50 μm is prepared.

Next, a 160° C. elastic modulus of the film cross-section sample is measured as an indentation elastic modulus using a nanoindentation method. The indentation elastic modulus is measured by using a microhardness meter (product name “DUH-W201”, manufactured by Shimadzu Corporation) to apply a load at a loading rate of 0.5 mN/sec with a Vickers indenter, holding a maximum load of 10 mN for 10 seconds, and then unloading at a loading rate of 0.5 mN/sec.

In a case where the laminate includes a support such as a metal layer, the elastic modulus of the layer B at 160° C. included in the laminate described below is measured by preparing a film cross-section sample (length of 2 mm, width of 2 mm) produced by obliquely cutting the layer B with a microtome so that the cross section of the layer B is 50 μm after etching the laminate.

From the viewpoint of heat resistance, the elastic modulus of the polymer film at 260° C. is preferably 10 MPa to 0.1 MPa, more preferably 9.5 MPa to 0.1 MPa, and still more preferably 1.5 MPa to 0.1 MPa.

In the present disclosure, the elastic modulus of the polymer film at 260° C. is measured by the following method.

First, a film cross-section sample (length: 2 mm×width: 2 mm) produced by oblique cutting with a microtome to a thickness of 50 μm is prepared.

Next, a 260° C. elastic modulus of the film cross-section sample is measured as an indentation elastic modulus using a nanoindentation method. The indentation elastic modulus is measured by using a microhardness meter (for example, product name “DUH-W201”, manufactured by Shimadzu Corporation) to apply a load at a loading rate of 0.28 mN/sec with a Vickers indenter, holding a maximum load of 10 mN for 10 seconds, and then unloading at a loading rate of 0.28 mN/sec.

In a case where the laminate includes a support such as a metal layer, the elastic modulus of the layer B at 260° C. included in the laminate described below is measured by preparing a film cross-section sample (length of 2 mm, width of 2 mm) produced by obliquely cutting the layer B with a microtome so that the cross section of the layer B is 50 μm after etching the laminate.

From the viewpoint of heat resistance, the equilibrium moisture absorptivity of the polymer film at 85° C. and a relative humidity of 85% is preferably 2.2% by mass or less, more preferably 1.5% by mass or less, still more preferably 0.8% by mass or less, particularly preferably 0.5% by mass or less, and most preferably 0.25% by mass or less. The lower limit of the equilibrium moisture absorptivity may be 0% by mass. In the present disclosure, the equilibrium moisture absorptivity is measured as follows.

The polymer film is left at a temperature of 85° C. and a relative humidity of 85% for 24 hours to reach an equilibrium state, and then 0.1 g of the sample is used to measure a Karl Fischer moisture content at a temperature of 150° C. using a Karl Fischer moisture content measuring device and a moisture vaporization device attached thereto.

The moisture absorptivity is calculated from the measured moisture content/layered product mass×100 (%).

As the measuring device, “CA-03”, “VA-05”, and the like (manufactured by Mitsubishi Chemical Corporation) can be used.

The parallel moisture absorptivity of the laminate described below is measured by leaving the laminate instead of the polymer film.

The dielectric loss tangent of the polymer film is preferably 0.005 or less, and more preferably more than 0 and 0.003 or less.

In the present disclosure, the dielectric loss tangent is measured by the following method.

The dielectric loss tangent is measured by a resonance perturbation method at a frequency of 10 GHz. A 10 GHz cavity resonator (for example, “CP531” manufactured by Kanto Electronic Application & Development Inc.) is connected to a network analyzer (for example, “E8363B” manufactured by Agilent Technology Company), a polymer film is inserted into the cavity resonator, and the measurement is performed from the change in resonance frequency before and after the insertion for 96 hours in an environment of a temperature of 25° C. and a humidity of 60% RH.

The dielectric loss tangent of the laminate described below is measured by inserting the laminate instead of the polymer film.

From the viewpoint of dielectric loss tangent, heat resistance, and step followability, the average thickness of the polymer film is preferably 5 μm to 90 μm, more preferably 10 μm to 70 μm, and still more preferably 15 μm to 50 μm.

In the present disclosure, a measuring method of the average thickness is as follows.

The polymer film is cut along a plane perpendicular to a plane direction of the polymer film, thicknesses are measured at five or more points on a cross section thereof, and an average value thereof is defined as the average thickness.

The average thickness of each layer in the laminate described later is obtained by cutting the laminate along a plane perpendicular to a plane direction of the laminate, by measuring the thickness of five or more points in the cross section of each tank, and by calculating the average value of the measured values.

From the viewpoint of heat resistance and step followability, the polymer film according to the present disclosure preferably has a phase-separated structure including at least two phases.

In the present disclosure, the “phase-separated structure” means a structure in which at least two portions containing components different from each other are present in the polymer film or the layer.

Examples of the phase-separated structure include a sea-island structure, a co-continuous structure, a cylinder structure, and a lamella structure. The sea-island structure means a structure in which one phase of the at least two phases forms a continuous phase and the other phase is dispersed in a discontinuous manner. In addition, the co-continuous structure means a structure in which all of the at least two phases form a continuous phase. The cylinder structure means a structure having, in at least one phase of the at least two phases, a plurality of rod-like phases which are other phases. The lamella structure means a layered structure in which the at least two phases are alternately overlapped. Both the cylinder structure and the lamella structure are structures in which all of the at least two phases form a continuous phase, but they are distinguished from the co-continuous structure in that they have the above-described characteristics (rod-like or layered).

It is preferable that the polymer film according to the present disclosure has a phase-separated structure in which all of the at least two phases form a continuous phase. Specifically, the phase-separated structure in the polymer film according to the present disclosure is preferably the co-continuous structure, the cylinder structure, or the lamella structure.

The fact that the film has a phase-separated structure can be confirmed by a method of observing a morphology, evaluating a material distribution, evaluating a mechanical property distribution, or the like for the film surface, the film cross section, or both the film surface and the film cross section. The morphological observation can be performed using a known optical microscope, an electron microscope, or the like. The material distribution evaluation can be performed using imaging such as infrared spectroscopy, Raman spectroscopy, and an X-ray photoelectron spectroscopy apparatus. The evaluation of the mechanical property distribution can be performed using an atomic force microscope.

In one embodiment, whether or not the polymer film has a phase-separated structure can be confirmed by performing differential scanning calorimetry (DSC) on the entire surface. Specifically, in a case where the glass transition temperature (Tg) of the resin is detected to be equal to or lower than room temperature (25° C.) and the Tg of the resin is detected to be equal to or higher than room temperature, it can be determined that phase separation occurs.

The phase-separated structure can be formed of a polymer described later, a thermoplastic resin such as an elastomer, and at least one of a thermoplastic resin or a cured product of a curing agent.

### Polymer

Examples of the polymer include thermoplastic resins such as a liquid crystal polymer, a fluororesin, a polymerized substance of a compound having a cyclic aliphatic hydrocarbon group and a group having an ethylenically unsaturated bond, a polyether ether ketone, a polyolefin, a polyamide, a polyester, a polyphenylene sulfide, a polyether ketone, a polycarbonate, a polyether sulfone, a polyphenylene ether and a modified product thereof, and a polyether imide; and thermosetting resins such as a phenol resin, an epoxy resin, a polyimide, and a cyanate resin.

Among the above, from the viewpoint of reducing the dielectric loss tangent, the polymer preferably includes a liquid crystal polymer.

### Liquid Crystal Polymer

The kind of the liquid crystal polymer is not particularly limited, and a known liquid crystal polymer can be used.

In addition, the liquid crystal polymer may be a thermotropic liquid crystal polymer which exhibits liquid crystallinity in a molten state, or may be a lyotropic liquid crystal polymer which exhibits liquid crystallinity in a solution state. In addition, in a case of the thermotropic liquid crystal, it is preferable that the liquid crystal is melted at a temperature of 450° C. or lower.

Examples of the liquid crystal polymer include a liquid crystal polyester, a liquid crystal polyester amide in which an amide bond is introduced into the liquid crystal polyester, a liquid crystal polyester ether in which an ether bond is introduced into the liquid crystal polyester, and a liquid crystal polyester carbonate in which a carbonate bond is introduced into the liquid crystal polyester.

In addition, as the liquid crystal polymer, from the viewpoint of liquid crystallinity, a polymer having an aromatic ring is preferable, and an aromatic polyester or an aromatic polyester amide is more preferable.

Furthermore, the liquid crystal polymer may be a polymer in which an imide bond, a carbodiimide bond, a bond derived from an isocyanate, such as an isocyanurate bond, or the like is further introduced into the aromatic polyester or the aromatic polyester amide.

In addition, it is preferable that the liquid crystal polymer is a fully aromatic liquid crystal polymer formed of only an aromatic compound as a raw material monomer.

Examples of the liquid crystal polymer include the following liquid crystal polymers.
1) a liquid crystal polymer obtained by polycondensing (i) an aromatic hydroxycarboxylic acid, (ii) an aromatic dicarboxylic acid, and (iii) at least one compound selected from the group consisting of an aromatic diol, an aromatic hydroxyamine, and an aromatic diamine.
2) a liquid crystal polymer obtained by polycondensing a plurality of kinds of aromatic hydroxycarboxylic acids.
3) a liquid crystal polymer obtained by polycondensing (i) an aromatic dicarboxylic acid and (ii) at least one compound selected from the group consisting of an aromatic diol, an aromatic hydroxyamine, and an aromatic diamine.
4) a liquid crystal polymer obtained by polycondensing (i) polyester such as polyethylene terephthalate and (ii) an aromatic hydroxycarboxylic acid.

Here, the aromatic hydroxycarboxylic acid, the aromatic dicarboxylic acid, the aromatic diol, the aromatic hydroxyamine, and the aromatic diamine may be each independently replaced with a polycondensable derivative.

A melting point of the liquid crystal polymer is preferably equal to or higher than 250° C., more preferably 250° C. to 350° C., and still more preferably 260° C. to 330° C.

In the present disclosure, the melting point is measured using a differential scanning calorimetry apparatus. For example, the measurement is performed using product name “DSC-60A Plus” (manufactured by Shimadzu Corporation). A temperature rising rate in the measurement is set to 10° C./minute.

A weight-average molecular weight of the liquid crystal polymer is preferably 1,000,000 or less, more preferably 3,000 to 300,000, still more preferably 5,000 to 100,000, and particularly preferably 5,000 to 30,000.

The liquid crystal polymer preferably contains an aromatic polyester amide from a viewpoint of further decreasing the dielectric loss tangent. The aromatic polyester amide is a resin having at least one aromatic ring and having an ester bond and an amide bond. Among these, from the viewpoint of heat resistance, the aromatic polyester amide is preferably a fully aromatic polyester amide.

The aromatic polyester amide is preferably a crystalline polymer. The polymer film according to the present disclosure preferably contains a crystalline aromatic polyester amide. Aromatic polyester amide included in the film is crystalline, whereby the dielectric loss tangent further decreases.

The crystalline polymer refers to a polymer having a clear endothermic peak, not a stepwise endothermic amount changed, in differential scanning calorimetry (DSC). Specifically, for example, this means that a half-width of an endothermic peak in measuring at a temperature rising rate 10° C./minute is within 10° C. A polymer in which a half-width exceeds 10° C. and a polymer in which a clear endothermic peak is not recognized are distinguished as an amorphous polymer from a crystalline polymer.

Aromatic polyester amide preferably contains a unit represented by Formula 1, a unit represented by Formula 2, and a unit represented by Formula 3.

—O—Ar1—CO Formula 1

—CO—Ar2—CO Formula 2

—NH—Ar3—O Formula 3

In Formula 1 to Formula 3, Ar1, Ar2, and Ar3 each independently represent a phenylene group, a naphthylene group, or a biphenylylene group.

Hereinafter, the unit represented by Formula 1 and the like are also referred to as “unit 1” and the like.

The unit 1 can be introduced, for example, using aromatic hydroxycarboxylic acid as a raw material.

The unit 2 can be introduced, for example, using aromatic dicarboxylic acid as a raw material.

The unit 3 can be introduced, for example, using aromatic hydroxylamine as a raw material.

Here, the aromatic hydroxycarboxylic acid, the aromatic dicarboxylic acid, the aromatic diol, and the aromatic hydroxylamine may be each independently replaced with a polycondensable derivative.

For example, the aromatic hydroxycarboxylic acid and the aromatic dicarboxylic acid can be replaced with aromatic hydroxycarboxylic acid ester and aromatic dicarboxylic acid ester, by converting a carboxy group into an alkoxycarbonyl group or an aryloxycarbonyl group.

The aromatic hydroxycarboxylic acid and the aromatic dicarboxylic acid can be replaced with aromatic hydroxycarboxylic acid halide and aromatic dicarboxylic acid halide, by converting a carboxy group into a haloformyl group.

The aromatic hydroxycarboxylic acid and the aromatic dicarboxylic acid can be replaced with aromatic hydroxycarboxylic acid anhydride and aromatic dicarboxylic acid anhydride, by converting a carboxy group into an acyloxycarbonyl group.

Examples of a polymerizable derivative of a compound having a hydroxy group, such as an aromatic hydroxycarboxylic acid and an aromatic hydroxyamine, include a derivative (acylated product) obtained by acylating a hydroxy group and converting the acylated group into an acyloxy group.

For example, the aromatic hydroxycarboxylic acid and the aromatic hydroxylamine can be each replaced with an acylated product by acylating a hydroxy group and converting the acylated group into an acyloxy group.

Examples of a polycondensable derivative of the aromatic hydroxylamine include a substance (acylated product) obtained by acylating an amino group to convert the amino group into an acylamino group.

For example, the aromatic hydroxyamine can be replaced with an acylated product by acylating an amino group and converting the acylated group into an acylamino group.

In Formula 1, Ar1 is preferably a p-phenylene group, a 2,6-naphthylene group, or a 4,4′-biphenylylene group, and more preferably a 2,6-naphthylene group.

In a case where Ar1 is a p-phenylene group, the unit 1 is, for example, a unit derived from p-hydroxybenzoic acid.

In a case where Ar1 is a 2,6-naphthylene group, the unit 1 is, for example, a unit derived from 6-hydroxy-2-naphthoic acid.

In a case where Ar1 is a 4,4′-biphenylylene group, the unit 1 is, for example, a unit derived from 4′-hydroxy-4-biphenylcarboxylic acid.

In Formula 2, Ar2 is preferably a p-phenylene group, an m-phenylene group, or a 2,6-naphthylene group, and more preferably an m-phenylene group.

In a case where Ar2 is a p-phenylene group, the unit 2 is, for example, a unit derived from terephthalic acid.

In a case where Ar2 is an m-phenylene group, the unit 2 is, for example, a unit derived from isophthalic acid.

In a case where Ar2 is a 2,6-naphthylene group, the unit 2 is, for example, a unit derived from 2,6-naphthalenedicarboxylic acid.

In Formula 3, Ar3 is preferably a p-phenylene group or a 4,4′-biphenylylene group, and more preferably a p-phenylene group.

In a case where Ar3 is a p-phenylene group, the unit 2 is, for example, a unit derived from p-aminophenol.

In a case where Ar3 is a 4,4′-biphenylylene group, the unit 2 is, for example, a unit derived from 4-amino-4′-hydroxybiphenyl.

With respect to the total content of the unit 1, the unit 2, and the unit 3, a content of the unit 1 is preferably 30 mol % or more, a content of the unit 2 is preferably 35% or less, and a content of the unit 3 is preferably 35 mol % or less.

The content of the unit 1 is preferably 30 mol % to 80 mol %, more preferably 30 mol % to 60 mol %, and particularly preferably 30 mol % to 40 mol % with respect to the total content of the unit 1, the unit 2, and the unit 3.

The content of the unit 2 is preferably 10 mol % to 35 mol %, more preferably 20 mol % to 35 mol %, and particularly preferably 30 mol % to 35 mol % with respect to the total content of the unit 1, the unit 2, and the unit 3.

The content of the unit 3 is preferably 10 mol % to 35 mol %, more preferably 20 mol % to 35 mol %, and particularly preferably 30 mol % to 35 mol % with respect to the total content of the unit 1, the unit 2, and the unit 3.

The total content of the units is a value obtained by totaling a substance amount (mol) of each unit. The substance amount of each unit is calculated by dividing a mass of each unit constituting aromatic polyester amide by a formula weight of each unit.

In a case where a ratio of the content of the unit 2 to the content of the unit 3 is expressed as [Content of unit 2] /[Content of unit 3] (mol/mol), the ratio is preferably 0.9/1 to 1/0.9, more preferably 0.95/1 to 1/0.95, and still more preferably 0.98/1 to 1/0.98.

Aromatic polyester amide may have two kinds or more of the unit 1 to the unit 3 each independently. Alternatively, aromatic polyester amide may have other units other than the unit 1 to the unit 3. A content of other units is preferably 10% by mole or less and more preferably 5% by mole or less with respect to the total content of all units.

Aromatic polyester amide is preferably produced by subjecting a source monomer corresponding to the unit constituting the aromatic polyester amide to melt polymerization.

The weight-average molecular weight of aromatic polyester amide is preferably equal to or less than 1,000,000, more preferably 3,000 to 300,000, still more preferably 5,000 to 100,000, and particularly preferably 5,000 to 30,000.

### Fluororesin

From the viewpoint of heat resistance and mechanical strength, the polymer may contain a fluororesin.

In the present disclosure, the kind of the fluororesin is not particularly limited, and a known fluororesin can be used.

Examples of the fluororesin include a homopolymer and a copolymer containing a unit derived from a fluorinated α-olefin monomer, that is, an α-olefin monomer containing at least one fluorine atom. In addition, examples of the fluororesin include a copolymer containing a unit derived from a fluorinated α-olefin monomer, and a unit derived from a non-fluorinated ethylenically unsaturated monomer reactive to the fluorinated α-olefin monomer.

Examples of the fluorinated α-olefin monomer include CF₂═CF₂, CHF═CF₂, CH₂—CF₂, CHCl═CHF, CClF═CF₂, CC₁₂═CF₂, CClF═CClF, CHF═CCl₂, CH₂—CClF, CC₁₂═CClF, CF₃CF—CF₂, CF₃CF═CHF, CF₃CH═CF₂, CF₃CH═CH₂, CHF₂CH═CHF, CF₃CF═CF₂, and perfluoro (alkyl having 2 to 8 carbon atoms) vinyl ether (for example, perfluoromethyl vinyl ether, perfluoropropyl vinyl ether, and perfluorooctyl vinyl ether). Among these, as the fluorinated α-olefin monomer, at least one monomer selected from the group consisting of tetrafluoroethylene (CF₂═CF₂), chlorotrifluoroethylene (CClF═CF₂), (perfluorobutyl) ethylene, vinylidene fluoride (CH₂═CF₂), and hexafluoropropylene (CF₂═CFCF₃) is preferable.

Examples of the non-fluorinated ethylenically unsaturated monomer include ethylene, propylene, butene, and an ethylenically unsaturated aromatic monomer (for example, styrene and α-methylstyrene).

The fluorinated α-olefin monomer may be used alone or in combination of two or more thereof.

In addition, the non-fluorinated ethylenically unsaturated monomer may be used alone or in combination of two or more thereof.

Examples of the fluororesin include polychlorotrifluoroethylene (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (FEP), poly(tetrafluoroethylene-propylene) (FEPM), poly(tetrafluoroethylene-perfluoropropylene vinyl ether), poly(tetrafluoroethylene-perfluoroalkyl vinyl ether) (PFA) (for example, poly(tetrafluoroethylene-perfluoropropyl vinyl ether)), polyvinyl fluoride (PVF), polyvinylidene fluoride (PVDF), poly(vinylidene fluoride-chlorotrifluoroethylene), perfluoropolyether, perfluorosulfonic acid, and perfluoropolyoxetane.

The fluororesin may have a unit derived from fluorinated ethylene or fluorinated propylene.

The fluororesin may be used alone or in combination of two or more thereof. The fluororesin is preferably FEP, PFA, ETFE, or PTFE.

The FEP is available from Du Pont as the trade name of TEFLON (registered trademark) FEP or from DAIKIN INDUSTRIES, LTD. as the trade name of NEOFLON FEP. The PFA is available from DAIKIN INDUSTRIES, LTD. as the trade name of NEOFLON PFA, from Du Pont as the trade name of TEFLON (registered trademark) PFA, or from Solvay Solexis as the trade name of HYFLON PFA.

The fluororesin more preferably includes PTFE. The PTFE may be a PTFE homopolymer, a partially modified PTFE homopolymer, or a combination including one or both of these. The partially modified PTFE homopolymer preferably contains a unit derived from a comonomer other than tetrafluoroethylene in an amount of less than 1% by mass based on the total mass of the polymer.

The fluororesin may be a crosslinkable fluoropolymer having a crosslinkable group. The crosslinkable fluoropolymer can be crosslinked by a known crosslinking method in the related art. One of the representative crosslinkable fluoropolymers is a fluoropolymer having (meth)acryloyloxy. For example, the crosslinkable fluoropolymer can be represented by Formula: H₂C═CR′COO—(CH₂)ₙ—R—(CH₂)ₙ—OOCR′═CH₂.

In the formula, R is an oligomer chain having a unit derived from the fluorinated α-olefin monomer, R′ is H or —CH3, and n is 1 to 4. R may be a fluorine-based oligomer chain having a unit derived from tetrafluoroethylene.

In order to initiate a radical crosslinking reaction through the (meth)acryloyloxy group in the fluororesin, by exposing the fluoropolymer having a (meth)acryloyloxy group to a free radical source, a crosslinked fluoropolymer network can be formed. The free radical source is not particularly limited, and suitable examples thereof include a photoradical polymerization initiator and an organic peroxide. Appropriate photoradical polymerization initiators and organic peroxides are well known in the art. The crosslinkable fluoropolymer is commercially available, and examples thereof include Viton B manufactured by Du Pont.

### Polymerized Substance of Compound Which has Cyclic Aliphatic Hydrocarbon Group and Group Having Ethylenically Unsaturated Bond

The polymer may include a polymerized substance of a compound having a cyclic aliphatic hydrocarbon group and a group having an ethylenically unsaturated bond.

Examples of the polymerized substance of a compound which has a cyclic aliphatic hydrocarbon group and a group having an ethylenically unsaturated bond include thermoplastic resins having a unit derived from a cyclic olefin monomer such as norbornene and a polycyclic norbornene-based monomer.

The polymerized substance of a compound which has a cyclic aliphatic hydrocarbon group and a group having an ethylenically unsaturated bond may be a ring-opened polymer of the above-described cyclic olefin, a hydrogenated product of a ring-opened copolymer using two or more cyclic olefins, or an addition polymer of a cyclic olefin and a linear olefin or aromatic compound having an ethylenically unsaturated bond such as a vinyl group. In addition, a polar group may be introduced into the polymerized substance of a compound which has a cyclic aliphatic hydrocarbon group and a group having an ethylenically unsaturated bond.

The polymerized substance of a compound which has a cyclic aliphatic hydrocarbon group and a group having an ethylenically unsaturated bond may be used alone or in combination of two or more thereof.

A ring structure of the cyclic aliphatic hydrocarbon group may be a single ring, a fused ring in which two or more rings are fused, or a crosslinked ring.

Examples of the ring structure of the cyclic aliphatic hydrocarbon group include a cyclopentane ring, a cyclohexane ring, a cyclooctane ring, an isophorone ring, a norbornane ring, and a dicyclopentane ring.

The compound which has a cyclic aliphatic hydrocarbon group and a group having an ethylenically unsaturated bond is not particularly limited, and examples thereof include a (meth)acrylate compound having a cyclic aliphatic hydrocarbon group, a (meth)acrylamide compound having a cyclic aliphatic hydrocarbon group, and a vinyl compound having a cyclic aliphatic hydrocarbon group. Among these, preferred examples thereof include a (meth)acrylate compound having a cyclic aliphatic hydrocarbon group. In addition, the compound which has a cyclic aliphatic hydrocarbon group and a group having an ethylenically unsaturated bond may be a monofunctional ethylenically unsaturated compound or a polyfunctional ethylenically unsaturated compound.

The number of cyclic aliphatic hydrocarbon groups in the compound which has a cyclic aliphatic hydrocarbon group and a group having an ethylenically unsaturated bond may be 1 or more, and may be 2 or more.

It is sufficient that the polymerized substance of a compound which has a cyclic aliphatic hydrocarbon group and a group having an ethylenically unsaturated bond is a polymer obtained by polymerizing at least one compound which has a cyclic aliphatic hydrocarbon group and a group having an ethylenically unsaturated bond, and it may be a polymerized substance of two or more kinds of the compound which has a cyclic aliphatic hydrocarbon group and a group having an ethylenically unsaturated bond or a copolymer with other ethylenically unsaturated compounds having no cyclic aliphatic hydrocarbon group.

In addition, the polymerized substance of a compound which has a cyclic aliphatic hydrocarbon group and a group having an ethylenically unsaturated bond is preferably a cycloolefin polymer.

### Polyphenylene Ether

The polymer may contain a polyphenylene ether.

In the polyphenylene ether, from the viewpoint of dielectric loss tangent and heat resistance, the average number of molecular terminal phenolic hydroxyl groups per molecule (the number of terminal hydroxyl groups) is preferably 1 to 5 and more preferably 1.5 to 3.

The number of terminal hydroxyl groups in the polyphenylene ether can be found, for example, from a standard value of a product of the polyphenylene ether. In addition, the number of terminal hydroxyl groups is expressed as, for example, an average value of the number of phenolic hydroxyl groups per molecule of all polyphenylene ethers present in 1 mol of the polyphenylene ether.

The polyphenylene ether may be used alone or in combination of two or more thereof.

Examples of the polyphenylene ether include a polyphenylene ether including 2,6-dimethylphenol and at least one of bifunctional phenol or trifunctional phenol, and poly(2,6-dimethyl-1,4-phenylene oxide). More specifically, the polyphenylene ether is preferably a compound having a structure represented by Formula (PPE).

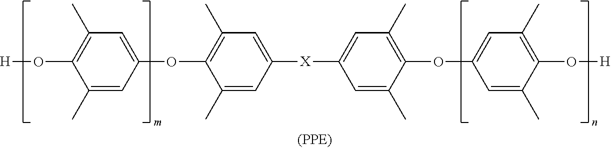

In Formula (PPE), X represents an alkylene group having 1 to 3 carbon atoms or a single bond, m represents an integer of 0 to 20, n represents an integer of 0 to 20, and the sum of m and n represents an integer of 1 to 30.

Examples of the alkylene group in X described above include a dimethylmethylene group.

In a case where heat curing is performed after film formation, from the viewpoint of heat resistance and film-forming property, a weight-average molecular weight (Mw) of the polyphenylene ether is preferably 500 to 5,000 and more preferably 500 to 3,000. In addition, in a case where the heat curing is not performed, the weight-average molecular weight (Mw) of the polyphenylene ether is not particularly limited, but is preferably 3,000 to 100,000 and more preferably 5,000 to 50,000.

### Aromatic Polyether Ketone

The polymer having a dielectric loss tangent of 0.01 or less may be an aromatic polyether ketone.

The aromatic polyether ketone is not particularly limited, and a known aromatic polyether ketone can be used.

The aromatic polyether ketone is preferably a polyether ether ketone.

The polyether ether ketone is one kind of the aromatic polyether ketone, and is a polymer in which bonds are arranged in the order of an ether bond, an ether bond, and a carbonyl bond. It is preferable that the bonds are linked to each other by a divalent aromatic group.

The aromatic polyether ketone may be used alone or in combination of two or more thereof.

Examples of the aromatic polyether ketone include polyether ether ketone (PEEK) having a chemical structure represented by Formula (P1), polyether ketone (PEK) having a chemical structure represented by Formula (P2), polyether ketone ketone (PEKK) having a chemical structure represented by Formula (P3), polyether ether ketone ketone (PEEKK) having a chemical structure represented by Formula (P4), and polyether ketone ether ketone ketone (PEKEKK) having a chemical structure represented by Formula (P5).

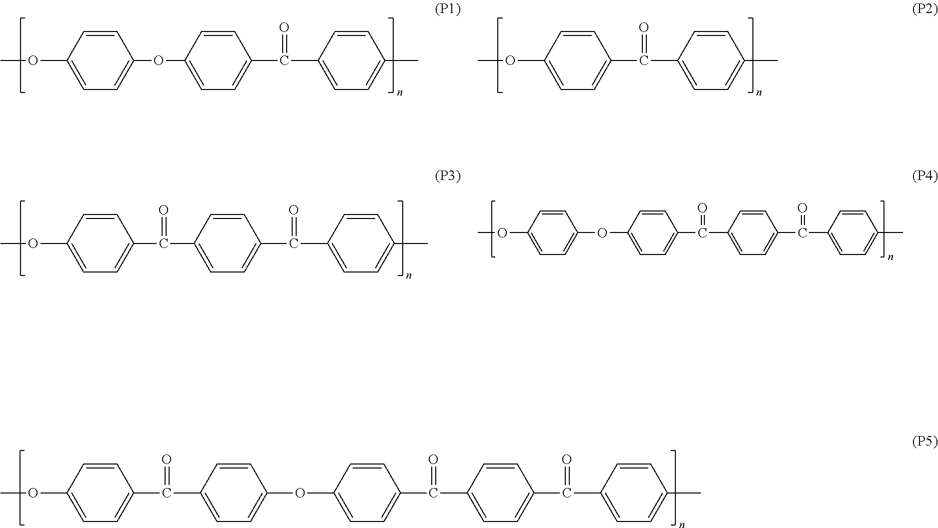

From the viewpoint of mechanical properties, each n of Formulae (P1) to (P5) is preferably 10 or more and more preferably 20 or more. On the other hand, from the viewpoint that the aromatic polyether ketone can be easily produced, n is preferably 5,000 or less and more preferably 1,000 or less. That is, n is preferably 10 to 5,000 and more preferably 20 to 1,000.

From the viewpoint of dielectric loss tangent of the polymer film, a content of the polymer with respect to the total mass of the polymer film is preferably 10% by mass or more, more preferably 15% by mass or more, still more preferably 20% by mass to 60% by mass, and particularly preferably 20% by mass to 40% by mass.

In a case where the polymer includes a liquid crystal polymer (preferably an aromatic polyester amide), from the viewpoint of reducing the dielectric loss tangent, the content of the liquid crystal polymer with respect to the total mass of the polymer is preferably 50% by mass or more, more preferably 70% by mass or more, still more preferably 90% by mass or more, and may be 100% by mass.

### Thermoplastic Resin Containing Unit Derived From Monomer Having Aromatic Hydrocarbon Group

From the viewpoint of dielectric loss tangent, heat resistance, and step followability, the polymer film preferably contains a thermoplastic resin containing a unit derived from a monomer having an aromatic hydrocarbon group, and more preferably contains a polystyrene-based elastomer.

Examples of the styrene-based elastomer include a styrene-butadiene-styrene block copolymer (SBS), a styrene-isoprene-styrene block copolymer (SIS), a polystyrene-poly(ethylene-propylene) diblock copolymer (SEP), a polystyrene-poly(ethylene-propylene)-polystyrene triblock copolymer (SEPS), a styrene-ethylene-butylene-styrene block copolymer (SEBS), a polystyrene-poly(ethylene/ethylene-propylene)-polystyrene triblock copolymer (SEEPS), a styrene-isobutylene-styrene block copolymer (SIBS), and hydrides thereof.

From the viewpoint of dielectric loss tangent, heat resistance, and step followability, the content of the above-described thermoplastic resin with respect to the total mass of the polymer film is preferably 40% by mass to 85% by mass, more preferably 40% by mass to 80% by mass, and still more preferably 60% by mass to 80% by mass.

### Curing Agent

From the viewpoint of dielectric loss tangent, heat resistance, and step followability, the polymer film preferably contains at least one of a curing agent or a cured product of the thermoplastic resin and the curing agent.

Examples of the curing agent include compounds having a maleimide group, an allyl group, a vinyl group, an epoxy group, an oxetanyl group, a cyanate group, a benzoxazine group, and the like.

From the viewpoint of laser processing suitability and step followability, the thermosetting compound preferably has at least one group selected from the group consisting of a maleimide group, an allyl group, a vinyl group, a cyanate group, and a benzoxazine group, and from the viewpoint of heat resistance, it is more preferable to contain a resin having at least one group selected from the group consisting of a maleimide group and an epoxy group.

From the viewpoint of dielectric loss tangent, heat resistance, and step followability, the content of the curing agent with respect to the total mass of the polymer film is preferably 1% by mass to 20% by mass, more preferably 3% by mass to 15% by mass, and still more preferably 5% by mass to 13% by mass.

### Filler

From the viewpoint of dielectric loss tangent, heat resistance, and step followability, the polymer film preferably contains a filler.

The filler may be in a particle shape or a fibrous shape. In addition, the filler may be an inorganic filler or an organic filler. From the viewpoint of dielectric loss tangent, heat resistance, and step followability of the polymer film, the filler is preferably an inorganic filler. As the organic filler, a known organic filler can be used.

Examples of a material of the organic filler include polyethylene, polystyrene, urea-formalin filler, polyester, cellulose, acrylic resin, fluororesin, cured epoxy resin, crosslinked benzoguanamine resin, crosslinked acrylic resin, a liquid crystal polymer, and a material containing two or more kinds of these.

In addition, the organic filler may be fibrous, such as nanofibers, or may be hollow resin particles.

Among these, as the organic filler, from the viewpoint of the dielectric loss tangent of the polymer film, the heat resistance, and the step followability, fluororesin particles, polyester-based resin particles, polyethylene particles, liquid crystal polymer particles, or cellulose-based resin nanofibers are preferable; polytetrafluoroethylene particles, polyethylene particles, or liquid crystal polymer particles are more preferable; and liquid crystal polymer particles are particularly preferable. Here, the liquid crystal polymer particles are not limited, but refer to particles obtained by polymerizing a liquid crystal polymer and pulverizing the liquid crystal polymer with a pulverizer or the like to obtain powdery liquid crystal. The liquid crystal polymer particles are preferably smaller than the thickness of each layer.

From the viewpoint of dielectric loss tangent, heat resistance, and step followability of the polymer film, the average particle diameter of the organic filler is preferably 5 nm to 20 μm and more preferably 100 nm to 10 μm.

As the inorganic filler, a known inorganic filler can be used.

Examples of the material of the inorganic filler include boron nitride (BN), Al₂O₃, aluminum nitride (AlN), TiO₂, silica (SiO₂), barium titanate, strontium titanate, aluminum hydroxide, calcium carbonate, and a material containing two or more of these.

Among these, the inorganic filler is preferably at least one selected from the group consisting of silica, aluminum hydroxide, and boron nitride.

An average particle diameter of the inorganic filler is preferably approximately 20% to approximately 40% of the thickness of a layer A, and for example, the average particle diameter may be selected from 25%, 30%, or 35% of the thickness of the layer A. In a case where the particles or fibers are flat, the average particle diameter indicates a length in a short side direction.

In addition, from the viewpoint of dielectric loss tangent, heat resistance, and step followability of the polymer film, the average particle diameter of the inorganic filler is preferably 5 nm to 20 μm, more preferably 10 nm to 10 μm, still more preferably 20 nm to 1 μm, and particularly preferably 25 nm to 500 nm.

The polymer film may contain only one or two or more kinds of the fillers.

In a case where the polymer film contains a filler, from the viewpoint of dielectric loss tangent, heat resistance, and step followability of the polymer film, the content of the filler is preferably 3% by mass to 25% by mass, more preferably 5% by mass to 23% by mass, and still more preferably 10% by mass to 20% by mass with respect to the total mass of the polymer film.

### Other Additives

The polymer film may contain an additive other than the above-described components. Known additives can be used as other additives. Specific examples of the other additives include a leveling agent, an antifoaming agent, an antioxidant, an ultraviolet absorbing agent, a flame retardant, and a colorant.

### Laminate

The laminate according to the present disclosure is a laminate including a layer A, and a layer B on at least one surface of the layer A, in which the layer B contains a polymer, has an elastic modulus of 10 MPa or less at 160° C., and has an elastic modulus of 0.1 MPa or more at 260° C., and the laminate has an equilibrium moisture absorptivity of 2.5% by mass or less at 85° C. and a relative humidity of 85%, and a dielectric loss tangent of 0.01 or less.

The equilibrium moisture absorptivity of the laminate at 85° C. and a relative humidity of 85% is preferably 2.2% by mass or less, more preferably 1.5% by mass or less, still more preferably 0.8% by mass or less, particularly preferably 0.5% by mass or less, and most preferably 0.25% by mass or less. The equilibrium moisture absorptivity may be 0% by mass.

The dielectric loss tangent of the laminate is preferably 0.005 or less and more preferably more than 0 and 0.003 or less.

### Layer A

The layer A can contain a polymer. The polymer is as described in the polymer film, and the description of the preferred kind, content, and the like thereof will be omitted here.

The layer A may contain a thermoplastic resin containing a unit derived from a monomer having an aromatic hydrocarbon group, a curing agent, a cured product of the thermoplastic resin and the curing agent, a filler, other additives, and the like. These are as described in the polymer film, and the description thereof will be omitted here.

The average thickness of the layer A is not particularly limited, but from the viewpoint of dielectric loss tangent, heat resistance, and step followability, it is preferably 5 μm to 90 μm, more preferably 10 μm to 70 μm, and particularly preferably 15 μm to 50 μm.

From the viewpoint of step followability, the elastic modulus of the layer A at 160° C. is preferably 50 MPa to 2000 MPa, more preferably 70 MPa to 1500 MPa, and still more preferably 150 MPa to 950 MPa.

From the viewpoint of heat resistance and step followability, a ratio of an elastic modulus of the layer A at 160° C. to an elastic modulus of the layer B at 160° C. (elastic modulus of layer A at 160° C./elastic modulus of layer B at 160° C.) is preferably 50 or more, more preferably 100 or more, still more preferably 200 or more, and particularly preferably 1000 or more. The upper limit of the above-described ratio may be 2,000.

In the present disclosure, the elastic modulus of the layer A at 160° C. is measured by the following method.

The polymer film or the laminate is obliquely cut with a microtome so that the cross section of the layer A is 50 μm, to produce a cross-sectional sample (length: 2 mm×width: 2 mm), and the indentation elastic modulus at 160° C. is measured with a microhardness meter (product name “DUH-W201”, manufactured by Shimadzu Corporation) equipped with a Vickers indenter, using a nanoindentation method.

In a case where the layer A is thin and it is difficult to apply the nanoindentation method, the measurement is performed using a sample obtained by scraping off an unnecessary layer with a razor or removing a metal layer using a known wet etching method with an aqueous solution of ferric chloride or the like, followed by washing with pure water and drying the sample.

### Layer B

The layer B can contain a polymer. The polymer is as described in the polymer film, and the description of the preferred kind, content, and the like thereof will be omitted here.

The layer B may contain a thermoplastic resin containing a unit derived from a monomer having an aromatic hydrocarbon group, a curing agent, a cured product of the thermoplastic resin and the curing agent, a filler, other additives, and the like. These are as described in the polymer film, and the description thereof will be omitted here.

Since the elastic modulus at 160° C., the elastic modulus at 260° C., the equilibrium moisture absorptivity at 85° C. and a relative humidity of 85%, the dielectric loss tangent, the average thickness, and the like of the layer B are the same as those of the polymer film, the description thereof will be omitted here.

In addition, the layer B preferably has the above-described phase-separated structure.

### Layer C

The laminate according to the present disclosure has the layer C, and may have the layer B, the layer A, and the layer C in this order.

The layer C is preferably an adhesive layer. In addition, the layer C is preferably a surface layer (outermost layer).

The layer C can contain a polymer. The polymer is as described in the polymer film, and the preferred type thereof will not be described here.

From the viewpoint of adhesiveness, the content of the polymer with respect to the total mass of the layer C is preferably 50% by mass to 100% by mass, more preferably 60% by mass to 99.8% by mass, and still more preferably 70% by mass to 99.7% by mass.

The layer C may contain a thermoplastic resin containing a unit derived from a monomer having an aromatic hydrocarbon group, a curing agent, a cured product of the thermoplastic resin and the curing agent, a filler, other additives, and the like. These are as described in the polymer film, and the description thereof will be omitted here.

The average thickness of the layer C is not particularly limited, but from the viewpoint of dielectric loss tangent, heat resistance, and step followability, it is preferably 0.1 μm to 10 μm, more preferably 0.5 μm to 8 μm, and particularly preferably 1 μm to 5 μm.

### Production Method of Laminate

The production method of a laminate according to the present disclosure is not particularly limited, and a known method can be referred to.

Suitable examples of the film forming method include a co-casting method, a multilayer coating method, and a co-extrusion method. Among these, the film forming method is preferably a co-casting method.

In a case where the multilayer structure in the laminate is produced by the co-casting method or the multilayer coating method, it is preferable that the co-casting method or the multilayer coating method is performed by using a composition for forming the layer A, a composition for forming the layer B, a composition for forming the layer C, or the like obtained by dissolving or dispersing components of each layer, such as the liquid crystal polymer, in a solvent.

Examples of the solvent include halogenated hydrocarbons such as dichloromethane, chloroform, 1,1-dichloroethane, 1,2-dichlorocthane, 1,1,2,2-tetrachloroethane, 1-chlorobutane, chlorobenzene, and o-dichlorobenzene; halogenated phenols such as p-chlorophenol, pentachlorophenol, and pentafluorophenol; ethers such as diethyl ether, tetrahydrofuran, and 1,4-dioxane; ketones such as acetone and cyclohexanone; esters such as ethyl acetate and γ-butyrolactone; carbonates such as ethylene carbonate and propylene carbonate; amines such as triethylamine; nitrogen-containing heterocyclic aromatic compounds such as pyridine; nitriles such as acetonitrile and succinonitrile; amides such as N,N-dimethylformamide, N,N-dimethylacetamide, and N-methylpyrrolidone; urea compounds such as tetramethylurea; nitro compounds such as nitromethane and nitrobenzene; sulfur compounds such as dimethyl sulfoxide and sulfolane; and phosphorus compounds such as hexamethylphosphoramide and tri-n-butyl phosphate. Among these, two or more kinds thereof may be used in combination.

From the viewpoint of low corrosiveness and satisfactory handleability, a solvent containing, as a main component, an aprotic compound, particularly an aprotic compound having no halogen atom is preferable as the solvent, and the proportion of the aprotic compound in the entire solvent is preferably 50% by mass to 100% by mass, more preferably 70% by mass to 100% by mass, and particularly preferably 90% by mass to 100% by mass. In addition, from the viewpoint of easily dissolving the liquid crystal polymer, as the above-described aprotic compound, it is preferable to use an amide such as N,N-dimethylformamide, N,N-dimethylacetamide, tetramethylurea, and N-methylpyrrolidone, or an ester such as γ-butyrolactone; and it is more preferable to use N,N-dimethylformamide, N,N-dimethylacetamide, or N-methylpyrrolidone.

In addition, as the solvent, from the viewpoint of easily dissolving the liquid crystal polymer, a solvent containing a compound having a dipole moment of 3 to 5 as a main component is preferable, and a proportion of the compound having a dipole moment of 3 to 5 in the entire solvent is preferably 50% by mass to 100% by mass, more preferably 70% by mass to 100% by mass, and particularly preferably 90% by mass to 100% by mass.

It is preferable to use the compound having a dipole moment of 3 to 5 as the above-described aprotic compound.

In addition, as the solvent, from the viewpoint of ease removal, a solvent containing, as a main component, a compound having a boiling point of 220° C. or lower at 1 atm is preferable, and a proportion of the compound having a boiling point of 220° C. or lower at 1 atm in the entire solvent is preferably 50% by mass to 100% by mass, more preferably 70% by mass to 100% by mass, and particularly preferably 90% by mass to 100% by mass.

It is preferable to use the compound having a boiling point of 220° C. or lower at 1 atm as the above-described aprotic compound.

In addition, in the production method of the polymer film according to the present disclosure, in a case where the polymer film is produced by the co-casting method, the multilayer coating method, the co-extrusion method, or the like, a support may be used. Examples of the support include a metal drum, a metal band, a glass plate, a resin film, and a metal foil. Among these, the support is preferably a metal drum, a metal band, or a resin film.

Examples of the resin film include a polyimide (PI) film, and examples of commercially available products thereof include U-PILEX S and U-PILEX R (manufactured by Ube Corporation), KAPTON (manufactured by Du Pont-Toray Co., Ltd.), and IF30, IF70, and LV300 (manufactured by SKC Kolon PI, Inc.).

In addition, the support may have a surface treatment layer formed on the surface so that the support can be easily peeled off. Hard chrome plating, a fluororesin, or the like can be used as the surface treatment layer.

The average thickness of the resin film support is not particularly limited, but is preferably 25 μm to 75 μm and more preferably 50 μm to 75 μm.

In addition, a method for removing at least a part of the solvent from a cast or applied film-like composition (a coating film) is not particularly limited, and a known drying method can be used.

### Stretching

In the laminate according to the present disclosure, stretching can be combined as appropriate from the viewpoint of controlling molecular alignment and adjusting thermal expansion coefficiency and mechanical properties. The stretching method is not particularly limited, and a known method can be referred to, and the stretching method may be carried out in a solvent-containing state or in a dry film state. The stretching in the solvent-containing state may be carried out by gripping and stretching the film, or may be carried out by utilizing self-contraction due to drying without stretching. The stretching is particularly effective for the purpose of improving the breaking elongation and the breaking strength, in a case where brittleness of the film is reduced by addition of an inorganic filler or the like.

### Use Application

The polymer film and the laminate according to the present disclosure can be used for various applications. Among the various applications, the polymer film can be used suitably as a film for an electronic component such as a printed wiring board and more suitably for a flexible printed circuit board.

In addition, the polymer film and the laminate according to the present disclosure can be suitably used as a liquid crystal polymer film and a laminate for metal adhesion.

### Metallized Laminate

The metallized laminate according to the present disclosure includes the polymer film according to the present disclosure or the laminate according to the present disclosure, and a metal layer or a metal wire disposed on at least one surface of the polymer film or the laminate.

The metal layer or the metal wire may be made of a material known in the related art, and is preferably made of silver or copper and more preferably made of copper.

The metal layer or the metal wire may be disposed on both surfaces of the polymer film or the laminate. In this case, the two metal layers or metal wires may be metal layers or metal wires having the same material, thickness, and shape, or may be metal layers or metal wires having different materials, thicknesses, and shapes. From the viewpoint of adjusting the characteristic impedance, the two metal layers or metal wires may be metal layers or metal wires having different materials and thicknesses.

In one embodiment, the metal layer is a rolled metal foil formed by a rolling method or an electrolytic metal foil formed by an electrolytic method.

The peel strength between the polymer film or the laminate and the metal layer or the metal wire at 260° C. is preferably 0.02 kN/m or more, more preferably 0.05 kN/m or more, and still more preferably 0.08 kN/m or more. The upper limit of the peel strength may be 3 kN/m.

In the present disclosure, the peel strength between the polymer film or the laminate and the metal layer or the metal wire at 260° C. is measured by the following method.

A peeling test piece having a width of 1.0 cm is prepared from a laminate (metallized laminate) of a polymer film or a laminate and a metal layer or a metal wire, the peeling test piece is fixed to a flat plate with a double-sided adhesive tape, and a strength (kN/m) in a case where the peeling test piece is peeled off at a rate of 50 mm/min according to the 180° method in conformity with JIS C 5016 (1994) is measured.

The average thickness of the metal layer is not particularly limited, but is preferably 2 μm to 20 μm, more preferably 3 μm to 18 μm, and still more preferably 5 μm to 12 μm.

In a case where the metal layer is a copper foil, the copper foil may be a copper foil with a carrier that is formed on a support (carrier) in a peelable manner.

As the carrier, a known carrier can be used. An average thickness of the carrier is not particularly limited, but is preferably 10 μm to 100 μm and more preferably 18 μm to 50 μm.

From the viewpoint of suppressing distortion of the metal wire in a case of being bonded to the metal wire, the average thickness of the layer B is preferably larger than the average thickness of the metal.

The metal layer may be a metal layer having a circuit pattern. It is also preferable that the metal layer is processed into a desired circuit pattern by, for example, etching, and a flexible printed circuit board is formed. The etching method is not particularly limited, and a known etching method can be used.

### Production Method of Metallized Laminate

The metallized laminate according to the present disclosure can be produced by using a metal layer or a metal wire as a support in the production method of the laminate according to the present disclosure.

A metal layer or a metal wire may be provided on a surface of the laminate opposite to the side on which the support is provided, by heat sealing or the like.

### EXAMPLES

Hereinafter, the present disclosure will be described in more detail with reference to examples. The materials, the used amounts, the proportions, the treatment contents, the treatment procedures, and the like described in the following examples can be appropriately changed without departing from the gist of the present disclosure. Therefore, the scope of the present disclosure is not limited to the following specific examples.

The details of the polymer and the additive (components other than the polymer) used for forming each layer of the laminate, and the copper foil are as follows.

### Polymer or Elastomer

Aromatic polyester amide P1 synthesized according to the following synthesis method (in Table 1, referred to as “P1”)

### Synthesis of Aromatic Polyester Amide P1

940.9 g (5.0 mol) of 6-hydroxy-2-naphthoic acid, 415.3 g (2.5 mol) of isophthalic acid, 377.9 g (2.5 mol) of acetaminophen, 867.8 g (8.4 mol) of acetic anhydride are put in a reactor comprising a stirring device, a torque meter, a nitrogen gas introduction pipe, a thermometer, and a reflux condenser, gas in the reactor is substituted with nitrogen gas, a temperature increases from a room temperature (23° C., the same applies hereinafter) to 140° C. over 60 minutes while stirring under a nitrogen gas flow, and refluxing is performed at 140° C. for three hours.

Next, the temperature was raised from 150° C. to 300° C. over 5 hours while distilling off by-produced acetic acid and unreacted acetic anhydride, and maintained at 300° C. for 30 minutes. Thereafter, a content is taken out from the reactor and cooled to the room temperature. The obtained solid was pulverized by a pulverizer to obtain a powdered aromatic polyester amide A1a. A flow start temperature of the aromatic polyester amide A1a was 193° C. In addition, the aromatic polyester amide A1a was a fully aromatic polyester amide.

The aromatic polyester amide A1a was subjected to solid phase polymerization by increasing the temperature from room temperature to 160° C. over 2 hours and 20 minutes in a nitrogen atmosphere, increasing the temperature from 160° C. to 180° C. over 3 hours and 20 minutes, and maintaining the temperature at 180° C. for 5 hours, and then the resultant was cooled. Next, the resultant was pulverized by a pulverizer to obtain a powdered aromatic polyester amide A1b. A flow start temperature of the aromatic polyester amide A1b was 220° C.

Aromatic polyester amide A1b is subjected to solid phase polymerization by increasing the temperature from the room temperature to 180° C. for one hour and 25 minutes, next increasing the temperature from 180° C. to 255° C. over six hours and 40 minutes, and maintaining the temperature at 255° C. for five hours in a nitrogen atmosphere, and then, is cooled, and powdered aromatic polyester amide P1 is obtained.

A flow start temperature of the aromatic polyester amide P1 was 302° C. A melting point of aromatic polyester amide Pl was measured using a differential scanning calorimetry apparatus, and the result was 311° C. Solubility of aromatic polyester amide P1 with respect to N-methylpyrrolidone at 140° C. is equal to or greater than 1% by mass.

· Polyimide precursor PI synthesized according to the following synthesis method (hereinafter, referred to as “PI” in Table 1)

### Synthesis of Polyimide Precursor PI

68.74 kg of 3,3′,4,4′-biphenyltetracarboxylic dianhydride (BPDA) and 23.6 kg of para-phenylenediamine (PDA) were added to 850 kg of N,N-dimethylformamide (DMF), and the mixture was stirred and dissolved for 30 minutes in a nitrogen atmosphere to obtain a polymerized substance. The components added so far are non-thermoplastic block components, and the components added thereafter are thermoplastic block components. 14.5 kg of 4,4′-oxydiphthalic acid anhydride (ODPA) was put into the polymerization solution containing the non-thermoplastic block component, 6.8 kg of pyromellitic dianhydride (PMDA) was added thereto, 19.2 kg of 2,2-bis[4-(4-aminophenoxy)phenyl]propane (BAPP) was put thereinto, 17.2 kg of 4,4′-bis(4-aminophenoxy)biphenyl (BAPB) was put thereinto, and the mixture was stirred for 1 hour to obtain a polyamic acid PA-A having a viscosity of 2,500 poise at 23° C.

Acetic anhydride (1.6 mol with respect to 1 mol of the amide acid unit of the polyamic acid PA-A), isoquinoline (0.5 mol with respect to 1 mol of the amide acid unit of the polyamic acid PA-A), and DMF (the total mass of the acetic anhydride, isoquinoline, and DMF was 45% of the polyamic acid PA-A) were added to the polyamic acid PA-A to obtain a polyimide precursor (PI-A) solution. In a case where the additive shown in Table 1 was added, the mixture was further stirred at 25° C. for 30 minutes after the addition to obtain a polyimide precursor PI.
Hydrogenated styrene-ethylene-butylene-styrene block copolymer (SEBS): product name “TUFTEC M1913”, manufactured by Asahi Kasci Corporation, elastomer

### Additive

Liquid crystal polymer particles PP-1 synthesized according to the following synthesis method (in Table 1, referred to as “PP-1”)

### Preparation of Liquid Crystal Polymer Particles PP-1

1034.99 g (5.5 mol) of 2-hydroxy-6-naphthoic acid, 89.18 g (0.41 mol) of 2,6-naphthalenedicarboxylic acid, 236.06 g (1.42 mol) of terephthalic acid, 341.39 g (1.83 mol) of 4,4-dihydroxybiphenyl, and potassium acetate and magnesium acetate as a catalyst were put in a reactor including a stirring device, a torque meter, a nitrogen gas introduction pipe, a thermometer, and a reflux condenser. Gas in the reactor is substituted with nitrogen gas, and then, acetic anhydride (1.08 molar equivalent with respect to a hydroxyl group) is further added.

A temperature increases from a room temperature to 150° C. over 15 minutes while stirring under a nitrogen gas flow, and refluxing is performed at 150° C. for two hours.

Next, the temperature was raised from 150° C. to 310° C. over 5 hours while distilling off by-produced acetic acid and unreacted acetic anhydride, and a polymerized substance was cooled to room temperature. An obtained polymerized substance increases in temperature from the room temperature to 295° C. over 14 hours, and is subjected to solid phase polymerization at 295° C. for one hour. After the solid phase polymerization, the temperature was lowered to room temperature over 5 hours, thereby obtaining liquid crystal polymer particles PP-1. The liquid crystal polymer particles PP-1 has a median diameter (D50) of 7 μm, a dielectric loss tangent of 0.0007, and a melting point of 334° C.
Elastomer particles PP-2 (in Table 1, referred to as “PP-2”): frozen and pulverized product (average particle diameter: 5.0 μm (D50)) of hydrogenated styrene-ethylene-butylene-styrene block copolymer (SEBS, product name “TUFTEC M1913”, manufactured by Asahi Kasei Corporation), thermoplastic resin
   Elastomer particles PP-3 (in Table 1, referred to as “PP-3”): hydrogenated styrene-isobutylene-styrene block copolymer particles, frozen and pulverized product of SIBSTAR 103T-UL manufactured by Kaneka Corporation (average particle diameter: 5.0 μm (D50)), thermoplastic resin
   Curing agent Cl (in Table 1, referred to as “C1”): jER YX8800, manufactured by Mitsubishi Chemical Corporation, condensed polyfunctional epoxy resin
   Curing agent C2 (in Table 1, referred to as “C2”): maleimide curing agent
   Curing agent C3 (in Table 1, referred to as “C3”): jER630, manufactured by Mitsubishi Chemical Corporation, aminophenol-type epoxy resin
   Silica particles Al (in Table 1, referred to as “Al”): SC2050-MB, manufactured by Admatechs Co., Ltd.
   Aluminum hydroxide particles A2 (in Table 1, referred to as “A2”): AO-502, manufactured by Admatechs Co., Ltd.
   Boron nitride particles A3 (in Table 1, referred to as “A3”): HP40MF100, manufactured by Mizushima Ferroalloy & Metal Co., Ltd.)

### Copper Foil

Copper foil M1 (in Table 1, referred to as “M1”): CF-T9DA-SV-18, manufactured by Fukuda Metal Foil & Powder Co., Ltd., average thickness: 18 μm
Copper foil M2 (in Table 1, referred to as “M2”): MT18FL, manufactured by Mitsui Mining & Smelting Co., Ltd., average thickness: 1.5 μm
Copper foil M3 (in Table 1, referred to as “M3”): CF-T4X-SV-18, manufactured by Fukuda Metal Foil & Powder Co., Ltd., average thickness: 18 μm

### Examples 1 to 9 and Comparative Examples 2 and 3

Solutions used for forming the layer A to the layer C were prepared according to the following method.

### Preparation of Solution for Layer A

The solution of the polymer or elastomer and the additive shown in Table 1 were mixed so as to have the mass ratio shown in Table 1, and N-methylpyrrolidone was added thereto so that the concentration of solid contents was 25% by mass, thereby obtaining a solution for a layer A.

### Preparation of Solution for Layer B

The solution of the polymer or elastomer and the additive shown in Table 1 were mixed so as to have the mass ratio shown in Table 1, and N-methylpyrrolidone was added thereto such that the concentration of solid contents was 20% by mass, thereby obtaining a solution for a layer B.

### Preparation of Solution for Layer C

8 parts of aromatic polyester amide P1 was added to 92 parts of N-methylpyrrolidone, and the mixture was stirred at 140° C. for 4 hours under a nitrogen atmosphere to obtain an aromatic polyester amide solution P1 (concentration of solid contents: 8% by mass). Next, the additives shown in Table 1 were mixed at the mass ratios shown in Table 1 to obtain a solution for a layer C.

### Preparation of Single-Sided Copper-Clad Laminated Plate

The obtained solutions for the layer C, the layer B, and the layer A were fed to a slot die coater equipped with a slide coater, and applied to the treated surface of the copper foil (first metal layer) shown in Table 1 in a three-layer configuration (layer C/layer A/layer B) by adjusting the flow rate so that the thickness after drying was the average thickness shown in Table 1. The solvent was removed from the coating film by drying at 40° C. for 4 hours. Further, a heat treatment was performed in a nitrogen atmosphere by raising the temperature from room temperature to 300° C. at 1° C./min and holding the temperature for 2 hours, thereby obtaining a laminate (single-sided copper-clad laminated plate) having a first metal layer (copper layer).

### Preparation of Double-Sided Copper-Clad Laminated Plate

The copper foil and the single-sided copper-clad laminated plate were laminated in this order so that the treated surface of the second metal layer (copper foil) shown in Table 1 was in contact with the layer B of the single-sided copper-clad laminated plate. A double-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a heat sealer (product name “MP-SNL”, manufactured by Toyo Seiki Seisaku-sho, Ltd.), the obtained double-sided copper-clad laminated plate precursor was heat-sealed for 60 minutes under conditions of 200° C. and 4 MPa to prepare a double-sided copper-clad laminated plate.

### Comparative Example 1

### Preparation of Laminate

The polyimide precursor PI-A solution was passed through a sintered fiber metal filter having a nominal pore diameter of 10 μm and further passed through a sintered fiber filter having a nominal pore diameter of 10 μm to obtain a solution for a comparative layer B. Then, the solution for the above-described layer B, the solution for the layer A, and the solution for the layer C for comparative purposes were fed to a casting die equipped with a feed block adjusted for co-casting, and cast on a stainless steel belt (support). After casting, the film was gradually heated in a range of 70° C. to 130° C. and peeled off from the support in a self-supporting gel film state. Subsequently, the laminate was obtained by stepwise heating in a nitrogen atmosphere while gripping with a pin tenter. The heating temperature at this time was set to 250° C. to 350° C.

### Preparation of Single-Sided Copper-Clad Laminated Plate

The treated surface of the copper foil shown in Table 1 was disposed on one surface of the obtained laminate so as to be in contact with the layer C, and using a laminator (“Vacuum laminator V-130” manufactured by Nikko Materials Co., Ltd.), a laminating treatment was performed for 1 minute under conditions of 140° C. and a laminating pressure of 0.4 MPa to obtain a precursor of a single-sided copper-clad laminated plate. Subsequently, using a heat scaler (“MP-SNL” manufactured by Toyo Seiki Seisaku-sho, Ltd.), the obtained single-sided copper-clad laminated plate precursor was heat-sealed for 10 minutes under conditions of 300° C. and 4.5 MPa to prepare a double-sided copper-clad laminated plate.

### Preparation of Double-Sided Copper-Clad Laminated Plate

The copper foil and the single-sided copper-clad laminated plate were laminated in this order such that the treated surface of the copper foil shown in Table 1 was in contact with the layer B of the single-sided copper-clad laminated plate. A double-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a heat sealer (product name “MP-SNL”, manufactured by Toyo Seiki Seisaku-sho, Ltd.), the obtained double-sided copper-clad laminated plate precursor was thermally compression-bonded for 60 minutes under conditions of 300° C. and 4 MPa to prepare a double-sided copper-clad laminated plate.

### Examples 12 to 17

### Preparation of Single-Sided Copper-Clad Laminated Plate

The obtained solution for a layer B was fed to a slot die coater equipped with a slide coater, and applied to the treated surface of the copper foil (first metal layer) shown in Table 1 in a single layer configuration (layer B) by adjusting the flow rate such that the thickness after drying was the average thickness shown in Table 1. The solvent was removed from the coating film by drying at 40° C. for 4 hours. Further, a heat treatment was performed in a nitrogen atmosphere by raising the temperature from room temperature to 300° C. at 1° C./min and holding the temperature for 2 hours, thereby obtaining a laminate (single-sided copper-clad laminated plate) having a first metal layer (copper layer).

### Preparation of Double-Sided Copper-Clad Laminated Plate

The copper foil and the single-sided copper-clad laminated plate were laminated in this order so that the treated surface of the second metal layer (copper foil) shown in Table 1 was in contact with the layer B of the single-sided copper-clad laminated plate. A double-sided copper-clad laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.). Subsequently, using a heat sealer (product name “MP-SNL”, manufactured by Toyo Seiki Seisaku-sho, Ltd.), the obtained double-sided copper-clad laminated plate precursor was heat-sealed for 60 minutes under conditions of 200° C. and 4 MPa to prepare a double-sided copper-clad laminated plate.

### Preparation of Polymer Film

The first metal layer and the second metal layer of the double-sided copper-clad laminated plate were removed with an aqueous solution of ferric chloride, and then dried after being washed with pure water to obtain a polymer film.

TABLE 1

| | | Layer C | | | | | Layer A | | | |
|---|---|---|---|---|---|---|---|---|---|---|
| | First | Polymer | | Additive | | | Polymer | | Additive | |
| | metal | | Content | | Content | Average | | Content | | Content |
| | layer | | (% by | | (% by | thickness | | (% by | | (% by |
| | Kind | Kind | mass) | Kind | mass) | (μm) | Kind | mass) | Kind | mass) |
| Comparative | M1 | — | — | — | — | — | P1 | 100 | — | — |
| Example 1 | | | | | | | | | | |
| Comparative | M1 | P1 | 99.6 | C3 | 0.4 | 3 | P1 | 100 | — | — |
| Example 2 | | | | | | | | | | |
| Comparative | M1 | P1 | 99.6 | C3 | 0.4 | 3 | P1 | 100 | — | — |
| Example 3 | | | | | | | | | | |
| Example 1 | M1 | P1 | 99.6 | C3 | 0.4 | 3 | P1 | 100 | — | — |
| Example 2 | M1 | P1 | 99.6 | C3 | 0.4 | 3 | P1 | 25 | PP-1 | 75 |
| Example 3 | M1 | P1 | 99.6 | C3 | 0.4 | 3 | P1 | 25 | PP-1 | 75 |
| Example 4 | M1 | P1 | 99.6 | C3 | 0.4 | 3 | P1 | 25 | PP-1 | 75 |
| Example 5 | M2 | P1 | 99.6 | C3 | 0.4 | 3 | P1 | 25 | PP-1 | 75 |
| Example 6 | M1 | P1 | 99.6 | C3 | 0.4 | 3 | P1 | 25 | PP-1 | 75 |
| Example 7 | M1 | P1 | 99.6 | C3 | 0.4 | 3 | P1 | 25 | PP-1 | 75 |
| Example 8 | M1 | P1 | 99.6 | C3 | 0.4 | 3 | P1 | 25 | PP-1 | 75 |
| Example 9 | M1 | P1 | 99.6 | C3 | 0.4 | 3 | P1 | 25 | PP-1 | 75 |
| Example 10 | M1 | P1 | 99.6 | C3 | 0.4 | 3 | P1 | 25 | PP-1 | 75 |
| Example 11 | M1 | P1 | 99.6 | C3 | 0.4 | 3 | P1 | 25 | PP-1 | 75 |
| Example 12 | M1 | — | — | — | — | — | — | — | — | — |
| Example 13 | M1 | — | — | — | — | — | — | — | — | — |
| Example 14 | M1 | — | — | — | — | — | — | — | — | — |
| Example 15 | M1 | — | — | — | — | — | — | — | — | — |
| Example 16 | M1 | — | — | — | — | — | — | — | — | — |
| Example 17 | M1 | — | — | — | — | — | — | — | — | — |

Layer B

| | Layer A | Polymer | | Additive-1 | | Additive-2 | | | |
|---|---|---|---|---|---|---|---|---|---|
| | Average | | Content | | Content | | Content | Average | Second |
| | thickness | | (% by | | (% by | | (% by | thickness | metal layer |
| | (μm) | Kind | mass) | Kind | mass) | Kind | mass) | (μm) | Kind |
| Comparative | 20 | P1 | 40 | PP-2 | 60 | — | — | 30 | M1 |
| Example 1 | | | | | | | | | |
| Comparative | 20 | P1 | 90 | PP-2 | 10 | — | — | 30 | M1 |
| Example 2 | | | | | | | | | |
| Comparative | 20 | P1 | 20 | PP-2 | 80 | — | — | 30 | M1 |
| Example 3 | | | | | | | | | |
| Example 1 | 20 | P1 | 40 | PP-2 | 60 | — | — | 30 | M1 |
| Example 2 | 20 | P1 | 40 | PP-2 | 60 | — | — | 30 | M1 |
| Example 3 | 20 | P1 | 60 | PP-2 | 40 | — | — | 30 | M1 |
| Example 4 | 20 | P1 | 40 | PP-3 | 60 | — | — | 30 | M1 |
| Example 5 | 20 | P1 | 40 | PP-3 | 60 | — | — | 30 | M2 |
| Example 6 | 20 | P1 | 40 | PP-3 | 60 | — | — | 30 | M3 |
| Example 7 | 20 | P1 | 28 | PP-2 | 60 | C1 | 12 | 30 | M1 |
| Example 8 | 20 | P1 | 28 | PP-2 | 60 | C2 | 12 | 30 | M1 |
| Example 9 | 20 | P1 | 22 | PP-2 | 60 | A1 | 18 | 30 | M1 |
| Example 10 | 20 | P1 | 22 | PP-2 | 60 | A2 | 18 | 30 | M1 |
| Example 11 | 20 | P1 | 22 | PP-2 | 60 | A3 | 18 | 30 | M1 |
| Example 12 | — | P1 | 40 | PP-3 | 60 | — | — | 30 | M1 |
| Example 13 | — | P1 | 34 | PP-3 | 60 | C1 | 6 | 30 | M1 |
| Example 14 | — | P1 | 34 | PP-3 | 60 | C2 | 6 | 30 | M1 |
| Example 15 | — | P1 | 22 | PP-3 | 60 | A1 | 18 | 30 | M1 |
| Example 16 | — | P1 | 22 | PP-3 | 60 | A2 | 18 | 30 | M1 |
| Example 17 | — | P1 | 22 | PP-3 | 60 | A3 | 18 | 30 | M1 |

### Measurement of Elastic Modulus of Layer B at 160° C. and 260° C.

The copper foil on the layer B side of the double-sided copper-clad laminated plate was removed with an aqueous solution of ferric chloride, and then dried after being washed with pure water. The layer B was obliquely cut with a microtome so that the cross section was 50 μm, thereby producing a cross-sectional sample (length: 2 mm×width: 2 mm).

Next, an elastic modulus at 160° C. and an elastic modulus 260° C. of the film cross-section sample were measured as indentation elastic moduli using a nanoindentation method. The indentation elastic modulus was measured by using a microhardness meter (product name “DUH-W201”, manufactured by Shimadzu Corporation) to apply a load at a loading rate of 0.5 mN/sec with a Vickers indenter, holding a maximum load of 10 mN for 10 seconds, and then unloading at a loading rate of 0.5 mN/sec. The results are shown in Table 2.

### Measurement of Dielectric Loss Tangent

The first metal layer and the second metal layer were etched from the double-sided copper-clad laminated plate.

The dielectric loss tangent of the taken-out laminate was measured by the following method. The results are shown in Table 1.

A dielectric constant was measured by a resonance perturbation method at a frequency of 10 GHz.

A 10 GHz cavity resonator (CP531 manufactured by KANTO Electronic Application and Development Inc.) is connected to a network analyzer (“E8363B” manufactured by Agilent Technology Co., Ltd.), the laminate is inserted into the cavity resonator, and the dielectric loss tangent of the laminate is measured from change in resonance frequency before and after insertion for 96 hours under an environment of a temperature of 25° C. and humidity of 60% RH. The results are shown in Table 2.

### Measurement of Equilibrium Moisture Absorptivity

The first metal layer and the second metal layer were etched from the double-sided copper-clad laminated plate.

The equilibrium moisture absorptivity of the laminate at 85° C. and a relative humidity of 85% was measured by the following method. The results are shown in Table 2.

The laminate was allowed to stand at a constant temperature and humidity of a temperature of 85° C. and a relative humidity of 85% for 24 hours to reach an equilibrium state, and then 0.1 g of the sample was used to measure a Karl Fischer moisture content at a temperature of 150° C. using a Karl Fischer moisture content measuring device and a moisture vaporization device (both manufactured by Mitsubishi Chemical Corporation) attached thereto.

The moisture absorptivity was calculated from the measured moisture content/laminate mass×100 (%).

### Evaluation of Step Followability

### Preparation of Substrate A With Wiring Patterns

A copper foil (product name “CF-T9DA-SV-18”, average thickness of 18 μm, manufactured by Fukuda Metal Foil & Powder Co., Ltd.) and a liquid crystal polymer film (product name “CTQ-50”, average thickness of 50 μm, manufactured by Kuraray Co., Ltd.) as a substrate were produced.

The copper foil, the substrate, and the copper foil were laminated in this order such that the treated surface of the copper foil was in contact with the substrate. A double-sided copper foil laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.).

Subsequently, using a heat sealer (product name “MP-SNL”, manufactured by Toyo Seiki Seisaku-sho, Ltd.), the obtained double-sided copper-clad laminated plate precursor was heat-sealed for 10 minutes under conditions of 300° C. and 4.5 MPa to prepare a double-sided copper-clad laminated plate.

The copper foils on both surfaces of the above-described double-sided copper-clad laminated plate were roughened, and a dry film resist was bonded thereto. The exposure and development were performed such that the wiring patterns remained, etching was performed, and the dry film was further removed to produce a substrate A with wiring patterns in which the line/space including the ground line and the three pairs of signal lines on both sides of the substrate was 100 μm/100 μm. A length of the signal line was 50 mm, and a width of the signal line was set such that characteristic impedance was 50 Ω.

### Preparation of Substrate B With Wiring Pattern

A copper foil (product name “MT18FL”, average thickness: 1.5 μm, with carrier copper foil (thickness: 18 μm), manufactured by Mitsui Mining & Smelting Co., Ltd.) and a liquid crystal polymer film (product name “CTQ-50”, average thickness: 50 μm, manufactured by Kuraray Co., Ltd.) as a substrate were produced.

The copper foil, the substrate, and the copper foil were laminated in this order such that the treated surface of the copper foil was in contact with the substrate. A single-sided copper foil laminated plate precursor was obtained by performing a laminating treatment for 1 minute under conditions of 140° C. and a laminating pressure of 0.4 MPa using a laminator (product name “Vacuum Laminator V-130”, manufactured by Nikko-Materials Co., Ltd.).

Subsequently, using a heat sealer (product name “MP-SNL”, manufactured by Toyo Seiki Seisaku-sho, Ltd.), the obtained single-sided copper-clad laminated plate precursor was heat-sealed for 10 minutes under conditions of 300° C. and 4.5 MPa to prepare a single-sided copper-clad laminated plate.

The carrier copper foil on the surface of the single-sided copper-clad laminated plate opposite to the substrate was peeled off, the exposed 1.5 μm copper foil was roughened, and a dry film resist was bonded thereto. The wiring pattern was exposed and developed, and a plating treatment was performed on a region where the resist pattern was not disposed. Further, the dry film resist was peeled off, and copper exposed in the peeling step was removed by flash etching to prepare a substrate B with wiring patterns having a line/space of 20 μm/20 μm.

The substrate A with a wiring pattern or the substrate B with a wiring pattern was overlaid on the layer A side of the single-sided copper-clad laminated plate produced in Examples and Comparative Examples, and subjected to a heat press for 1 hour under the conditions of 160° C. and 4 MPa to obtain a wiring board.

In the obtained wiring board, wiring patterns (a ground line and a signal line) were buried, and in a case where the substrate A with wiring patterns was used, the thickness of the wiring patterns was 18 μm, and in a case where the substrate B with wiring patterns was used, the thickness of the wiring patterns was 12 μm.

The wiring board was cut along the thickness direction with a microtome, and a cross section was observed with an optical microscope. A length L of a gap generated between the resin layer and the wiring pattern in an in-plane direction was measured. The average value at 10 sites was calculated, and the step followability was evaluated based on the following evaluation standard. The results are shown in Table 2.

### Evaluation Standard

A: No gap was recognized.
B: L was less than 1 μm.
C: L was 1 μm or more.

### Evaluation of Heat Resistance

The double-sided copper-clad laminated plates prepared in Examples and Comparative Examples were cut out to have a size of 30 mm×30 mm and used as samples. The sample was treated in a constant temperature and humidity tank at 85° C. and a relative humidity of 85% for 168 hours.

The treated sample was placed in an oven set to 260° C. and heated for 15 minutes. The sample after heating was cut with a razor, and the cross section was observed with an optical microscope, and the heat resistance was evaluated based on the following evaluation standards. The results are shown in Table 2.

### Evaluation Standard

A: No peeling was recognized between the layer B and the second metal layer.
B: Peeling was recognized between the layer B and the second metal layer with a width of 1 mm or less.
C: Peeling was recognized between the layer B and the second metal layer with a width of more than 1 mm.

### Calculation of Elastic Modulus of Layer A at 160° C./Elastic Modulus of Layer B at 160° C.

The first metal layer and the second metal layer were etched from the double-sided copper-clad laminated plate using an aqueous solution of ferric chloride.

A cross-sectional sample (length: 2 mm×width: 2 mm) was prepared by obliquely cutting the layer A with a microtome so that the cross section of the layer A was 50 μm, and the elastic modulus of the layer A at 160° C. was measured by the same method as that for the layer B. The results are shown in Table 2.

A ratio of the elastic modulus of the layer A at 160° C. to the elastic modulus of the layer B at 160° C. (elastic modulus of layer A at 160° C./elastic modulus of layer B at 160° C.) was calculated and summarized in Table 2.

### Measurement of Peel Strength of Double-Sided Copper-Clad Laminated Plate

A peeling test piece having a width of 1.0 cm was prepared from each of the double-sided copper-clad laminated plates produced in Examples and Comparative Examples, the double-sided copper-clad laminated plate was fixed to a flat plate with a double-sided adhesive tape, and the second metal layer was peeled off from the double-sided copper-clad laminated plate at a rate of 50 mm/min in an environment of 260° C. according to the 180° method in accordance with JIS C 5016 (1994), and the peel strength (kN/m) between the layer B and the second metal layer was measured. The results are shown in Table 2.

TABLE 2

| | | | | Equilibrium | Step followability | | | | Elastic modulus | Peel strength |
|---|---|---|---|---|---|---|---|---|---|---|
| | 160° C. | 260° C. | Dielectric | moisture | evaluation | | | 160° C. | of layer A | measurement |
| | elastic | elastic | loss tangent | absorptivity | Substrate | Substrate | | elastic | at 160° C./ | of double- |
| | modulus of | modulus of | of polymer | of polymer | A with | B with | Heat | modulus of | elastic modulus | sided copper- |
| | layer B | layer B | film/ | film/laminate | wiring | wiring | resistance | layer A | of layer B | clad laminated |
| | (MPa) | (MPa) | laminate | (% by mass) | pattern | pattern | evaluation | (MPa) | at 160° C. | plate (kN/m) |
| Comparative | 0.75 | 0.11 | 0.015 | 3.50 | A | A | C | 3400 | 4500 | 0.030 |
| Example 1 | | | | | | | | | | |
| Comparative | 11.20 | 0.31 | 0.003 | 1.10 | C | C | A | 100 | 43 | 0.060 |
| Example 2 | | | | | | | | | | |
| Comparative | 0.48 | 0.061 | 0.003 | 0.87 | A | A | C | 100 | 210 | 0.014 |
| Example 3 | | | | | | | | | | |
| Example 1 | 0.75 | 0.11 | 0.002 | 1.20 | A | A | B | 100 | 130 | 0.024 |
| Example 2 | 0.75 | 0.11 | 0.002 | 0.56 | A | A | B | 770 | 1020 | 0.023 |
| Example 3 | 1.40 | 0.15 | 0.002 | 0.79 | B | B | B | 770 | 570 | 0.023 |
| Example 4 | 0.60 | 2.74 | 0.002 | 0.25 | A | A | A | 770 | 1300 | 0.056 |
| Example 5 | 0.60 | 2.74 | 0.002 | 0.25 | A | A | A | 770 | 1300 | 0.076 |
| Example 6 | 0.60 | 2.74 | 0.002 | 0.25 | A | A | A | 770 | 1300 | 0.150 |
| Example 7 | 3.50 | 168 | 0.003 | 2.40 | B | B | A | 770 | 220 | 0.150 |
| Example 8 | 3.70 | 171 | 0.003 | 2.30 | B | B | A | 770 | 220 | 0.150 |
| Example 9 | 1.10 | 1.40 | 0.002 | 0.27 | A | A | A | 770 | 690 | 0.024 |
| Example 10 | 1.30 | 1.70 | 0.002 | 0.24 | A | A | A | 770 | 600 | 0.024 |
| Example 11 | 9.40 | 96 | 0.002 | 0.20 | B | B | A | 770 | 82 | 0.025 |
| Example 12 | 0.60 | 2.74 | 0.002 | 0.28 | A | A | A | — | — | 0.046 |
| Example 13 | 3.50 | 168 | 0.005 | 2.40 | B | B | A | — | — | 0.130 |
| Example 14 | 3.70 | 171 | 0.005 | 2.30 | B | B | A | — | — | 0.130 |
| Example 15 | 1.10 | 1.40 | 0.002 | 0.31 | A | A | A | — | — | 0.022 |
| Example 16 | 1.30 | 1.70 | 0.002 | 0.27 | A | A | A | — | — | 0.021 |
| Example 17 | 9.40 | 95 | 0.002 | 0.20 | B | B | A | — | — | 0.024 |

From the results shown in Table 2, it can be seen that the laminates of Examples 1 to 11, which are the laminates according to the present disclosure, have excellent step followability and excellent heat resistance as compared with the laminates of Comparative Examples 1 to 3.

In addition, it can be seen that the polymer films of Examples 12 to 17 are excellent in the step followability and the heat resistance, as in the laminates of Examples 1 to 11.

The disclosure of Japanese Patent Application No. 2022-197495 filed on Dec. 9, 2022 is incorporated in the present specification by reference. In addition, all documents, patent applications, and technical standards described in the present specification are herein incorporated by reference to the same extent that each individual document, patent application, or technical standard was specifically and individually indicated to be incorporated by reference.

What is claimed is:

1. A polymer film comprising:
a polymer,
wherein the polymer film has
an elastic modulus of 10 MPa or less at 160° C.,
an elastic modulus of 0.1 MPa or more at 260° C.,
an equilibrium moisture absorptivity of 2.5% by mass or less at 85° C. and a relative humidity of 85%, and
a dielectric loss tangent of 0.01 or less.

2. The polymer film according to claim 1,
wherein the polymer contains a liquid crystal polymer.

3. The polymer film according to claim 1,
wherein the polymer contains an aromatic polyester amide.

4. The polymer film according to claim 1, further comprising:
a thermoplastic resin containing a unit which is based on a monomer having an aromatic hydrocarbon group.

5. The polymer film according to claim 4, further comprising:
at least one of a curing agent or a cured product of the curing agent and the thermoplastic resin,
wherein the curing agent has at least one of an epoxy group or a maleimide group.

6. The polymer film according to claim 1, further comprising:
at least one inorganic filler selected from the group consisting of silica, aluminum hydroxide, and boron nitride.

7. A laminate comprising:
a layer A; and
a layer B on at least one surface of the layer A,
wherein the layer B comprises a polymer, has an elastic modulus of 10 MPa or less at 160° C., and has an elastic modulus of 0.1 MPa or more at 260° C., and
the laminate has an equilibrium moisture absorptivity of 2.5% by mass or less at 85° C. and a relative humidity of 85%, and a dielectric loss tangent of 0.01 or less.

8. The laminate according to claim 7,
wherein a ratio of an elastic modulus of the layer A at 160° C. to the elastic modulus of the layer B at 160° C. is 50 or more.

9. The laminate according to claim 7,
wherein the polymer comprises a liquid crystal polymer.

10. The laminate according to claim 7,
wherein the polymer comprises an aromatic polyester amide.

11. The laminate according to claim 7, further comprising:
a thermoplastic resin comprising a unit based on a monomer having an aromatic hydrocarbon group.

12. The laminate according to claim 11, further comprising:
at least one of a curing agent or a cured product of the curing agent and the thermoplastic resin,
wherein the curing agent has at least one of an epoxy group or a maleimide group.

13. The laminate according to claim 7, further comprising:
at least one inorganic filler selected from the group consisting of silica, aluminum hydroxide, and boron nitride.

14. The laminate according to claim 7, further comprising:
a layer C,
wherein the layer B, the layer A, and the layer C are provided in this order.

15. A metallized laminate comprising:
the polymer film according to claim 1; and
a metal layer or a metal wire disposed on at least one surface of the polymer film.

16. The metallized laminate according to claim 15, wherein a peel strength between the polymer film and the metal layer or the metal wire at 260° C. is 0.02 kN/m or more.

17. A metallized laminate comprising:
the laminate according to claim 7; and
a metal layer or a metal wire disposed on at least one surface of the laminate.

18. The metallized laminate according to claim 17,
wherein a peel strength between the laminate and the metal layer or the metal wire at 260° C. is 0.02 kN/m or more.
